(19) United States
(12) Patent Application Publication
(10) Pub. No.: US 2016/0260607 A1
(43) Pub. Date: Sep. 8, 2016

(54) METHOD OF FORMING A SEMICONDUCTOR STRUCTURE INCLUDING TWO PHOTORESIST EXPOSURE PROCESSES FOR PROVIDING A GATE CUT

(71) Applicant: GLOBALFOUNDRIES Inc., Grand Cayman (KY)

(72) Inventors: Remi Riviere, Dresden (DE); Thomas Merelle, Dresden (DE)

(21) Appl. No.: 14/639,620

(22) Filed: Mar. 5, 2015

(51) Int. Cl. H01L 21/033; H01L 27/11

(52) U.S. Cl. CPC H01L 21/0338; H01L 21/0332; H01L 21/0335; H01L 21/0337; H01L 27/1108

(57) ABSTRACT

A method includes providing a semiconductor structure and forming a plurality of gate structures over the semiconductor structure. The formation of the plurality of gate structures includes a first patterning process. The first patterning process includes a first photoresist exposure process and a second photoresist exposure process. In the first photoresist exposure process, a first photomask and a first illumination source pattern are used. The first photomask is adapted for providing a first gate cut photoresist pattern over a first area of the semiconductor structure. In the second photoresist exposure process, a second photomask and a second illumination source pattern that is different from the first illumination source pattern are used. The second photomask is adapted for providing a second gate cut photoresist pattern over a second area of the semiconductor structure.

### BACKGROUND OF THE INVENTION

1. Field of the Invention

Generally, the present disclosure relates to methods for the manufacturing of integrated circuits, and, in particular, to methods for the manufacturing of integrated circuits wherein multiple patterning techniques are used for the formation of gate structures.

2. Description of the Related Art

Integrated circuits include a large number of circuit elements which include, in particular, field effect transistors. In a field effect transistor, a gate electrode is provided that can be separated from a channel region by a gate insulation layer providing an electrical insulation between the gate electrode and the channel region. Adjacent the channel region, a source region and a drain region are formed, which are doped differently than the channel region. The source, channel and drain regions are provided in an active region of the field effect transistor.

For reducing the dimensions of field effect transistors, it has been proposed to use multiple patterning techniques, in particular double patterning techniques, for the formation of the gate electrodes of the field effect transistors. In the formation of gate electrodes by means of double patterning techniques, a first patterning process may be performed for defining elongated gate line features over a semiconductor material of the semiconductor structure wherein the active regions of the field transistors are to be formed. Each of the elongated gate line features may extend across the active regions of a number of field effect transistors, including transistors whose gate electrodes are not to be connected in the final integrated circuit. After the formation of the elongated gate line features, a further patterning process, which is denoted as a “gate cut process,” may be performed for defining cuts of the elongated gate line features between the active regions of those field effect transistors whose gate electrodes are not to be connected in the final integrated circuit.

When double patterning techniques for forming gate electrodes of field effect transistors as described above are employed for forming integrated circuits including a static random access memory (SRAM) array, the size of the gate cuts may have an influence on the performance of the SRAM array. A reduced gate cut size may allow increasing a width of the active regions of transistors in bitcells of the SRAM array without a bitcell area penalty, or reducing a bitcell area while maintaining the width of the active regions.

In particular, a greater width of the active regions of N-channel transistors in the bitcells of an SRAM array, which include pull down transistors and passgate transistors, may allow a reduction of electrical variability, since the active area under the transistor gate will increase. It may also increase transistor performance due to a reduction of the electrical resistance of the channel in the on-state of the transistors. This may allow a reduction of a dose of ions used in halo implants, which may lead to a lower gate induced drain leakage (GIDL) of the transistors, and may also contribute to a reduction of electrical variability, therefore improving bitcell stability.

Alternatively, a smaller gate cut size may allow a reduction of the bitcell area, while maintaining approximately the same performance of the bitcells.

However, the possibilities for reducing the size of gate cuts may be limited by the resolution of photolithography processes that are used in the patterning process for defining the gate cuts. The resolution of a photolithography process may depend on the numerical aperture of a projection lens that is used for projecting a photomask to a photoresist, and on the wavelength of light that is used for illuminating the photomask. Additionally, the resolution of the photolithography process may depend on the type of illumination of the photomask. The resolution of the photolithography process may be improved by using an off-axis illumination, wherein a beam of light from the illumination system of the photolithography tool is directed through the photomask such that it would strike the projection lens at the edge of the entrance pupil of the projection lens rather than at the center of the projection lens entrance pupil in the absence of the photomask.

There are different types of off-axis illumination, wherein different illumination patterns are employed. Which illumination pattern provides the best resolution of the photolithography process may depend on the pattern of the photomask that is to be projected to the semiconductor structure. For highly regular patterns which may occur, for example, in the formation of SRAM arrays or, in a similar manner, in the formation of memory arrays of other types, a different illumination pattern may be optimum than for more irregular patterns which may occur, for example, in the formation of logic circuits.

Therefore, when memory arrays and logic circuits are provided in the same semiconductor structure, the selection of the illumination pattern that is used in the photolithography process may require a compromise between the logic circuit and the memory array. This may limit the minimum size of the gate cut that is obtainable in the formation of the memory array.

The present disclosure provides methods that address the above-mentioned issues.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method disclosed herein includes providing a semiconductor structure and forming a plurality of gate structures over the semiconductor structure. The formation of the plurality of gate structures includes a first patterning process. The first patterning process includes a first photoresist exposure process and a second photoresist exposure process. In the first photoresist exposure process, a first photomask and a first illumination source pattern are used. The first photomask is adapted for providing a first gate cut photoresist pattern over a first area of the semiconductor structure. In the second photoresist exposure process, a second photomask and a second illumination source pattern that is different from the first illumination source pattern are used. The second photomask is adapted for providing a second gate cut photoresist pattern over a second area of the semiconductor structure.

### BRIEF DESCRIPTION OF THE DRAWINGS

The disclosure may be understood by reference to the following description taken in conjunction with the accompanying drawings, in which like reference numerals identify like elements, and in which:

FIG. 1 shows a schematic view of a photolithography tool;

FIG. 2 shows a schematic view of a semiconductor structure;

FIG. 3 shows an enlarged view of a portion of the semiconductor structure shown in FIG. 2;

FIGS. 4 and 5 show schematic views of photomasks;

FIGS. 6a, 6b, 7a and 7b show schematic views of illumination apertures; and

FIGS. 8a to 12d show schematic cross-sectional views of a semiconductor structure in stages of a method of manufacturing a semiconductor structure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

In embodiments disclosed herein, instead of one photomask as described above, two photomasks are used in the formation of a photoresist mask that is employed in a gate cut patterning process. A first gate cut photomask is provided. The first gate cut photomask is intended for areas with relatively irregular patterns, for example, areas of logic circuitry, and may be conventionally illuminated, for example, by means of a quadruple source. Additionally, a second gate cut photomask is provided. The second gate cut photomask is intended for static random access memory (SRAM) arrays with regular patterns and may be illuminated with an optimized source, for example, a dipole or freeform source. The freeform source may be provided by means of a source mask optimization process. Since the pattern of the SRAM array may be processed in a different manner than the pattern of the logic circuitry, using a source optimized for regular patterns, its aerial optical contrast may be higher, which may allow reduced manufacturable critical dimensions of gate cuts in SRAM arrays. Since areas with logic circuitry and areas with SRAM arrays are processed separately, the source optimized for the SRAM arrays need not impact the performance of photolithography in logic circuitry areas, which are not regular enough to benefit from the source optimized for the SRAM array area.

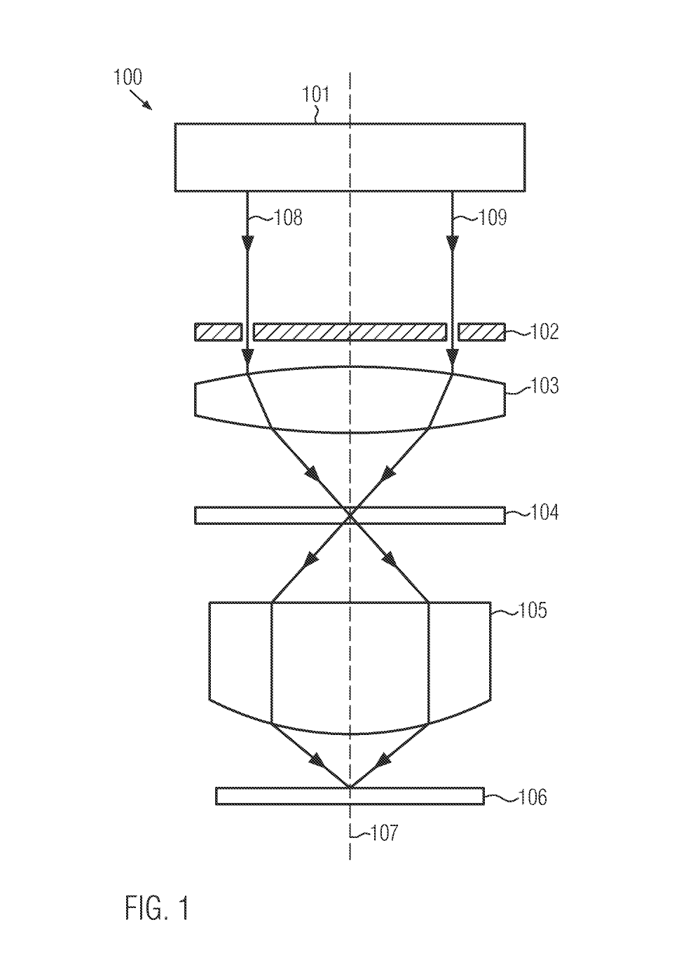

FIG. 1 shows a schematic view of a photolithography tool 100 that can be used in methods of manufacturing a semiconductor structure according to embodiments. The photolithography tool 100 may include a light source 101. The light source 101 may provide light, for example, extreme ultraviolet light, that is used for exposing a photoresist in a photolithography process. Reference numerals 108, 109 schematically denote light beams that are emitted by the light source 101.

Additionally, the photolithography tool 100 may include an illumination aperture 102 that is adapted for providing an illumination pattern. Examples of illumination apertures that may be provided as the aperture 102 will be described in more detail below.

The photolithography tool 100 may further include a condenser 103 that illuminates a photomask 104 with the light from the light source 101 that has passed through the illumination aperture 102. Examples of photomasks that may be provided as the photomask 104 will be described in more detail below. Between the photomask 104 and a semiconductor structure 106, a projection lens 105 may be provided that focuses an image of the photomask 104 to the semiconductor structure 106.

On the semiconductor structure 106, a photoresist may be provided. When the photomask 104 is projected to the photoresist using the projection lens 105, a pattern of exposed portions that corresponds to a pattern of photomask features on the photomask 104 may be formed in the photoresist. Thereafter, the photoresist may be developed, wherein, in the case of a positive development process, the exposed portions are removed and the unexposed portions remain on the semiconductor structure 106. Thus, a photoresist mask having a pattern in accordance with the pattern of photomask features of the photomask 104 may be formed on the semiconductor structure 106. In other embodiments, a negative development process and a photomask having a pattern of photomask features that is inverse to the photoresist mask to be formed on the semiconductor structure may be employed. In the following, embodiments wherein a positive development process is used will be described.

The light source 101, the illumination aperture 102, the condenser 103, the photomask 104, the projection lens 105 and the semiconductor structure 106 may be arranged along an optical axis 107 of the photolithography tool 100.

The semiconductor structure 106 may include a semiconductor wafer, for example, a bulk silicon wafer or a semiconductor-on-insulator (SOI) wafer. In the semiconductor structure 106, a plurality of chip areas may be provided. In each of the chip areas, one integrated circuit may be formed.

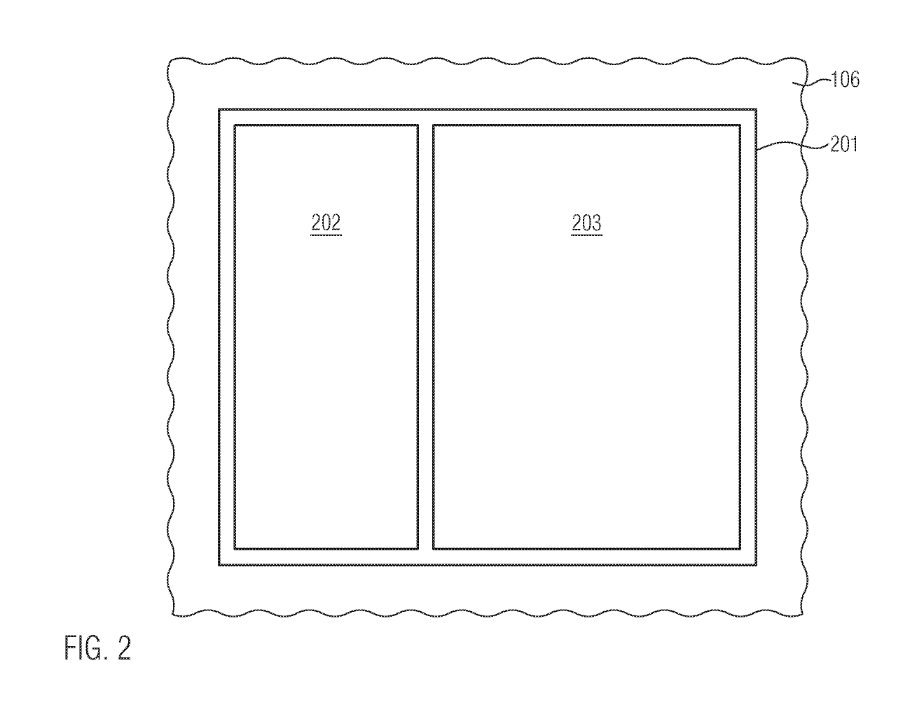

FIG. 2 shows a schematic top view of a portion of the semiconductor structure 106 that includes one chip area 201. The chip area 201 may include a logic circuit area 202 wherein logic circuitry of the integrated circuit formed in the chip area 201 is provided. Additionally, the chip area 201 may include a memory array area 203, wherein a memory array of the integrated circuit formed in the chip area 201 is provided. The arrangement of the logic circuit area 202 and the memory array area 203 illustrated in FIG. 2 is of an exemplary nature only. In some embodiments, a more complex arrangement of logic circuit areas and memory array areas may be provided. For example, in some embodiments, the arrangement may include one or more logic cores and one or more memory arrays. Other chip areas provided in the semiconductor structure 106 may have a configuration that is substantially identical to the configuration of the chip area 201.

In some embodiments, the memory array area 203 may include SRAM memory, wherein the SRAM memory may include bitcells that each include six transistors, or more complicated bitcells that include a greater number of transistors, for example, eight transistors or ten transistors. In some embodiments, the memory array area 203 may include embedded SRAM (eSRAM). In further embodiments, the memory array area 203 may include memory of types other than SRAM, for example, Dynamic Random Access Memory (DRAM) or Nonvolatile Random Access Memory (NVRAM), such as Magnetoresistive Random Access Memory (MRAM), Phase-change Random Access Memory (PRAM) and/or Ferroelectric Random Access Memory (FRAM).

In the following, embodiments wherein the memory array area 203 includes SRAM memory, and wherein each of the bitcells includes six transistors will be described in more detail.

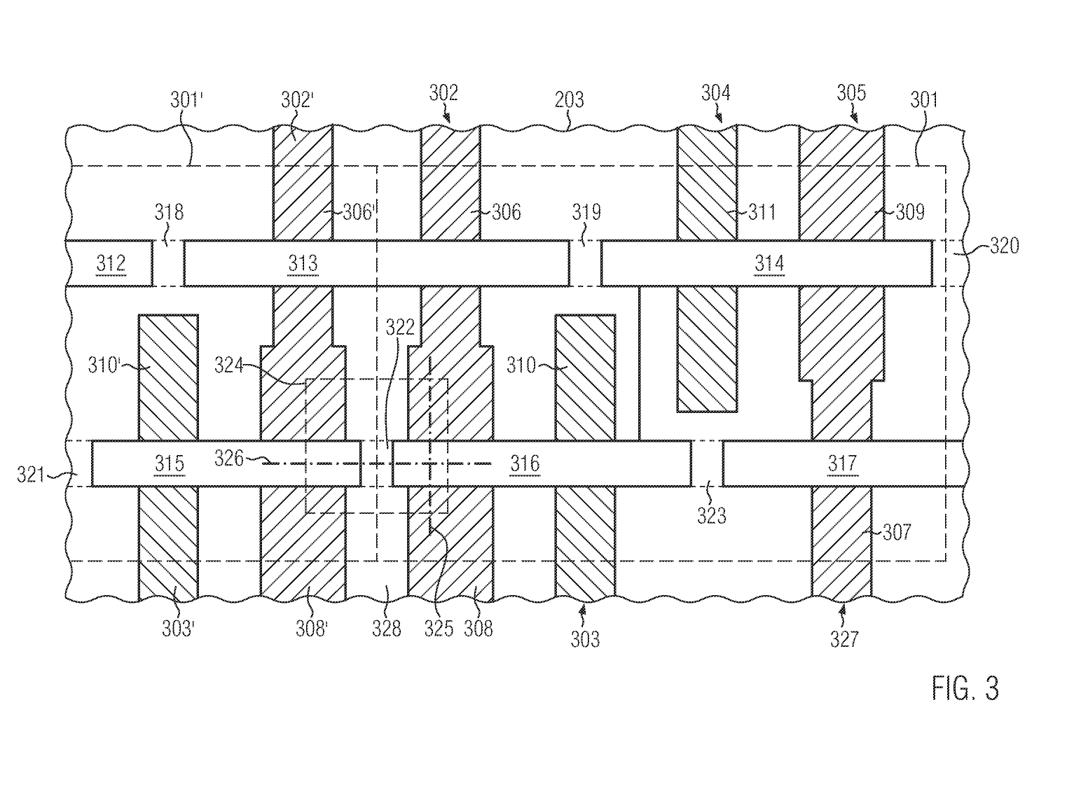

FIG. 3 shows a schematic top view of a portion of the memory array area 203 provided in the chip area 201 at a manufacturing stage of the semiconductor structure 106 that may be obtained after performing methods according to embodiments. The memory array area 203 may include a plurality of SRAM bitcells, wherein, in FIG. 3, a bitcell 301 and a portion of a bitcell 301′ that is arranged adjacent the bitcell 301 and has a configuration that is mirror symmetrical to the configuration of the bitcell 301 are shown.

The bitcell 301 may include passgate transistors 306, 307 and pull down transistors 308, 309 whose source, channel and drain regions are provided in active regions 302, 305. The passgate transistors 306, 307 and the pull down transistors 308, 309 may be N-channel transistors.

The SRAM cell 301 may further include pull up transistors 310, 311 whose source, channel and drain regions are provided in active regions 303, 304. The pull up transistors 310, 311 may be P-channel transistors. Accordingly, the active regions 302, 305 may have a different doping than the active regions 303, 304, as indicated in FIG. 3 by a different hatching.

In the bitcell 301′, passgate transistors similar to passgate transistors 306, 307, pull down transistors similar to pull down transistors 308, 309 and pull up transistors similar to pull up transistors 310, 311 may be provided. In FIG. 3, only a part of the transistors of the bitcell 301′ is shown, wherein components corresponding to components of the bitcell 301 are denoted by corresponding reference numerals having a prime (′).

In some embodiments, the transistors 306, 307, 308, 309, 310, 311, 306′, 308′, 310′ may be planar transistors. The active regions 302, 303, 304, 305, 302′, 303′ may be provided in a semiconductor material of a substrate 327. The semiconductor material of the substrate 327 may include silicon. Electrical insulation between the active regions 302 to 305, 302′, 303′ may be provided by a trench isolation structure 328 that may be provided in the form of trenches filled with an electrically insulating material such as silicon dioxide.

In the memory array area 203, gate structures may be provided, wherein gate structures in the portion of the memory array area shown in FIG. 3 are denoted by reference numerals 312 to 317. The gate structure 313 provides gate electrodes of the passgate transistors 306, 306′, the gate structure 314 provides gate electrodes of the pull up transistor 311 and the pull down transistor 309, the gate structure 315 provides gate electrodes of the pull down transistor 308′ and the pull up transistor 310′, and the gate structure 316 provides gate electrodes of the pull down transistor 308 and the pull up transistor 310. Gate structure 312, which is only partially shown in FIG. 3, provides gate electrodes of a pull up transistor and a pull down transistor of the bitcell 301′ that are not shown in FIG. 3, and gate structure 317 provides a gate electrode of the passgate transistor 307 as well as a gate electrode of a passgate transistor of a bitcell that is arranged on a side of the bitcell 301 opposite to the bitcell 301′.

The gate structures 312, 313, 314, and further gate structures that are arranged in a row along a direction that corresponds to the horizontal direction in the plane of drawing of FIG. 3 may be defined by an elongated gate line feature wherein gate cuts 318, 319, 320 are provided for separating gate structures 312, 313, 314 that are not connected to each other. Similarly, gate structures 315, 316, 317 and further gate structures arranged in a row along a direction corresponding to the horizontal direction in the view of FIG. 3 may be defined by another elongated gate line feature, wherein gate cuts 321, 322, 323 are provided for separating gate structures 315, 316, 317 that are not connected to each other.

As can be seen in FIG. 3, the pull down transistors 308, 308′, 309 may have a relatively large width, which may help to improve a stability of the bitcells 301, 301′. The possibilities for increasing the width of the pull down transistors 308, 308′, 309 may be limited by an extension of the gate cuts 320, 322 between the gate structures defining the gate electrodes of the pull down transistors 308, 308′, 309.

In the logic circuit area 202 of the chip area 201, field effect transistors and, optionally, other circuit elements such as resistors, diodes and/or capacitors may be provided. Similar to the gate structures 312 to 317 shown in FIG. 3, gate electrodes of field effect transistors in the logic circuit area 202 may be provided by gate structures that are defined by elongated gate line features. Gate cuts may be provided between gate structures defined by the same elongated gate line feature that are not to be electrically connected to each other.

The arrangement of gate structures, gate cuts and gate line features in the logic circuit area 202 may be less regular than the arrangement in the memory array area 203 that is illustrated in FIG. 3. In particular, there may be a greater variety of different lengths of gate structures corresponding to a more irregular spacing between gate cuts, and there may be different widths of gate cuts. Furthermore, different from the arrangement of the SRAM bitcell shown in FIG. 3, in the logic circuit area 202, there may be gate structures extending in different directions. For example, in the logic circuit area 202, there may be gate structures defined by elongated gate line features extending in a direction corresponding to the horizontal direction in the plane of drawing of FIG. 2, as well as gate structures defined by elongated gate line features extending in another direction corresponding to the vertical direction in the plane of drawing of FIG. 2.

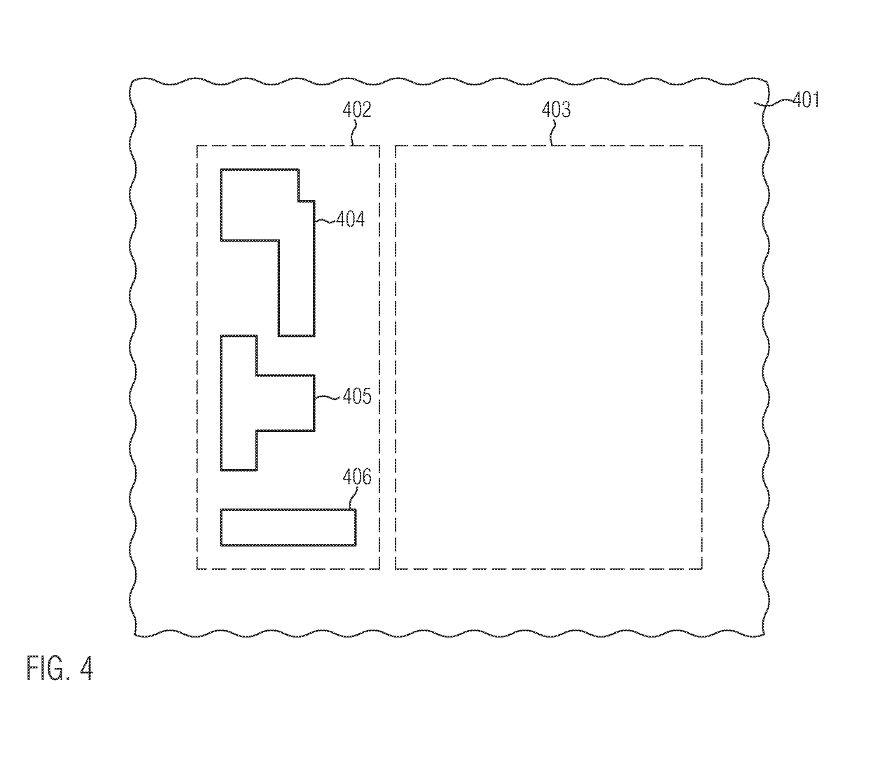

FIG. 4 schematically illustrates a portion of a photomask 401 that may be used in embodiments. The photomask 401 may include an area 402 corresponding to the logic circuit area 202 of the chip area 201 and an area 403 corresponding to the memory array area 203 of the chip area 201. Additionally, the photomask 401 may include portions corresponding to logic circuit areas and memory array areas in chip areas other than the chip area 201 that are to be formed in the semiconductor structure 106 and have a configuration corresponding to that of the portion shown in FIG. 4.

The photomask 401 may include a plurality of photomask features 404 to 406 that are provided in the area 402 of the photomask 401 corresponding to the logic circuit area 202. The number of the photomask features 404 to 406, as well as sizes and shapes of the photomask features 404 to 406, are of a schematic nature only. In practical implementations, a much greater number of photomask features may be provided in the area 402 of the photomask 401 corresponding to the logic circuit area 202, and the photomask features may have different shapes.

The photomask features 404 to 406 correspond to gate cuts that are to be provided in the logic circuit area 202 of the chip area 201. The photomask features 404 to 406 may be adapted such that light transmitted through the photomask features 404 to 406 exposes portions of a photoresist layer on the semiconductor structure 106 when the photomask is used in a photolithography process. Thus, a pattern of exposed photoresist corresponding to the pattern of the photomask features 404 to 406 may be formed in the photoresist layer. Light impinging on portions of the photomask 401 other than the photomask features 404 to 406 may be blocked by the photomask 401.

As shown in FIG. 4, in the area 403 of the photomask 401 corresponding to the memory array area 203 of the chip area 201, no photomask features need to be provided. Thus, the photomask 401 may be adapted for providing a gate cut photoresist pattern over the logic circuit area 202 only.

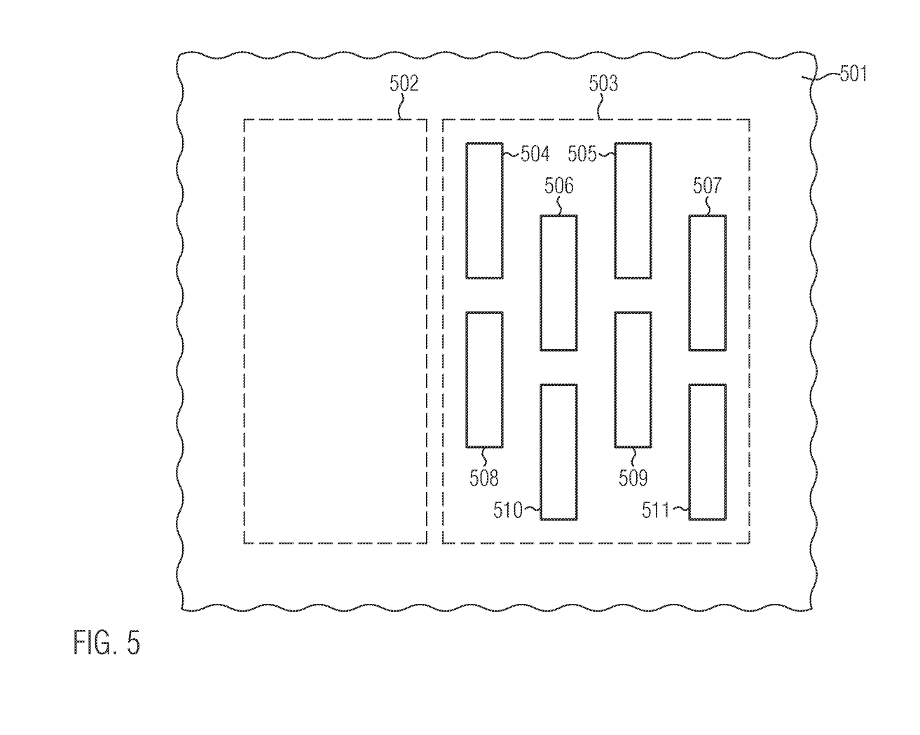

FIG. 5 shows a schematic view of a portion of a photomask 501 that includes an area 502 corresponding to the logic circuit area 202 and an area 503 corresponding to the memory array area 203 of the chip area 201 of the semiconductor structure 106. Additionally, similar to the photomask 401 described above with reference to FIG. 4, the photomask 501 may include portions that are used for patterning chip areas other than the chip area 201 and have a configuration corresponding to that of the portion shown in FIG. 5.

In the area 503 of the photomask 501 corresponding to the memory array area 203, photomask features 504 to 511 may be provided. The number and shapes of the photomask features 504 to 511 shown in FIG. 5 are of an exemplary nature only. In practical implementations, a much greater number of photomask features and/or different shapes of the photomask features may be provided.

The arrangement of the photomask features 504 to 511 of the photomask 501 corresponds to the arrangement of gate cuts in the memory array area 203 such as, for example, the gate cuts 318 to 323 shown in FIG. 3. The photomask features 504 to 511 may be adapted such that light impinging on any of the photomask features 504 to 511 is projected to a photoresist layer on the semiconductor structure 106 and exposes the photoresist, whereas light impinging on portions of the photomask 501 without photomask features is blocked by the photomask 501.

As shown in FIG. 5, in the area 502 of the photomask 501 corresponding to the logic circuit area 202, no photomask features need to be provided. Thus the photomask 501 may be adapted for providing a gate cut photoresist pattern over the memory array area 203 of the chip area 201 in the semiconductor structure 106 only.

The photomask features 504 to 511 of the photomask 501 may have a more regular arrangement than the photomask features 404 to 406 of the photomask 401. A greater part of the photomask features 504 to 511, or substantially all of the photomask features 504 to 511, may have a greater extension in a first direction (vertical in the view of FIG. 5) than in a second direction that is perpendicular to the first direction (horizontal in the view of FIG. 5).

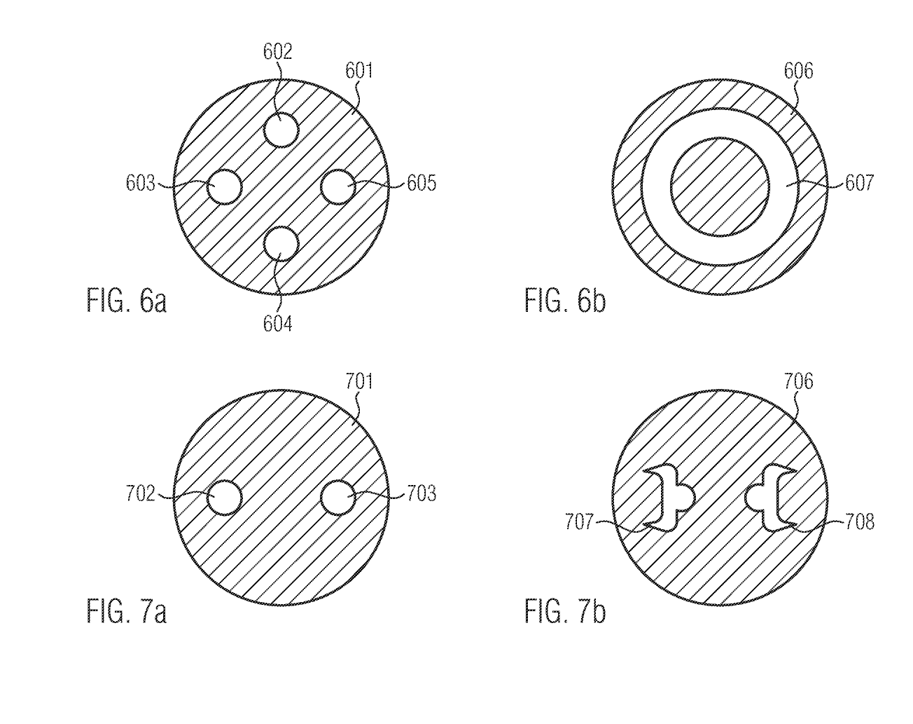

FIGS. 6a and 6b show examples of illumination apertures 601, 606. One of the illumination apertures 601, 606 may be provided in the photolithography tool 100 as the illumination aperture 102 when the photomask 401 is provided as the photomask 104.

The illumination aperture 601 is a quadrupole illumination aperture that may be used for providing a quadrupole illumination source pattern as the illumination source pattern for the photomask 401. The illumination aperture 601 includes four transmissive areas 602, 603, 604, 605. Light impinging on the transmissive areas 602 to 605 of the illumination aperture 601 from the light source 101 is transmitted to the condenser 103 and the photomask 401, so that a quadrupole illumination pattern of the photomask is provided.

The illumination aperture 606 shown in FIG. 6b includes an annular transmissive area 607. Light from the light source 101 impinging on the transmissive area 607 is transmitted to the condenser 103 and the photomask 401, so that a circular illumination pattern may be provided as the illumination pattern for the photomask 401.

A quadrupole illumination pattern as provided by the illumination aperture 601, or a circular illumination pattern as provided by the illumination aperture 606 may be particularly advantageous for patterning a photoresist provided on the semiconductor structure 106 with a relatively irregular pattern such as the pattern of gate cuts in the logic circuit area 202 of the chip area 201 of the semiconductor structure 106.

FIGS. 7a and 7b schematically illustrate illumination apertures 701, 706 that may be provided in the photolithography tool 100 as the illumination aperture 102 when the photomask 501 is provided as the photomask 104.

The illumination aperture 701 includes two transmissive areas 702, 703 that are adapted for providing a dipole illumination pattern as the illumination source pattern for the photomask 501. When used in combination with photomask 501 having a relatively regular arrangement of the photomask features 504 to 511 corresponding to the arrangement of gate cuts in the memory array area 203, the illumination aperture 701 may allow a greater resolution of the photolithography process than, for example, illumination aperture 601 or illumination aperture 606. This may allow a reduction of the widths of gate cuts in the memory array area 203 of the semiconductor structure 106, such as gate cuts 318 to 323 shown in FIG. 3.

The illumination aperture 706 shown in FIG. 7b includes two transmissive areas 707, 708, which have a more complex shape than the round transmissive areas 702, 703 of the illumination aperture 701. The illumination aperture 706 may provide a freeform illumination pattern of the photomask 501. The shape of the apertures 707, 708 may be provided on the basis of a source mask optimization (SMO) process, wherein a numerical optimization of the shapes of the apertures 707, 708 and/or the photomask features 504 to 511 with respect to a contrast of an aerial image of the photomask 501 is performed. The source mask optimization process may be performed in accordance with known source mask optimization techniques.

Providing freeform illumination aperture 706 may help to provide an even greater resolution of the photolithography process than providing the dipole illumination aperture 701.

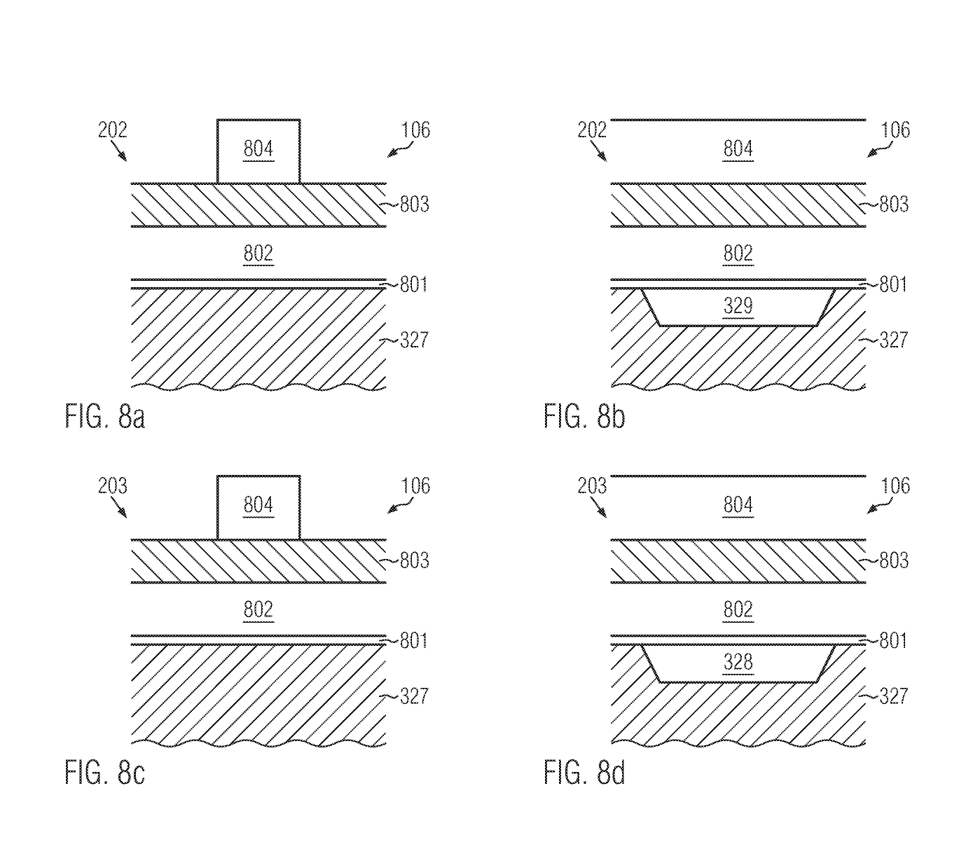

In the following, a method according to an embodiment will be described with reference to FIGS. 8a to 12d.

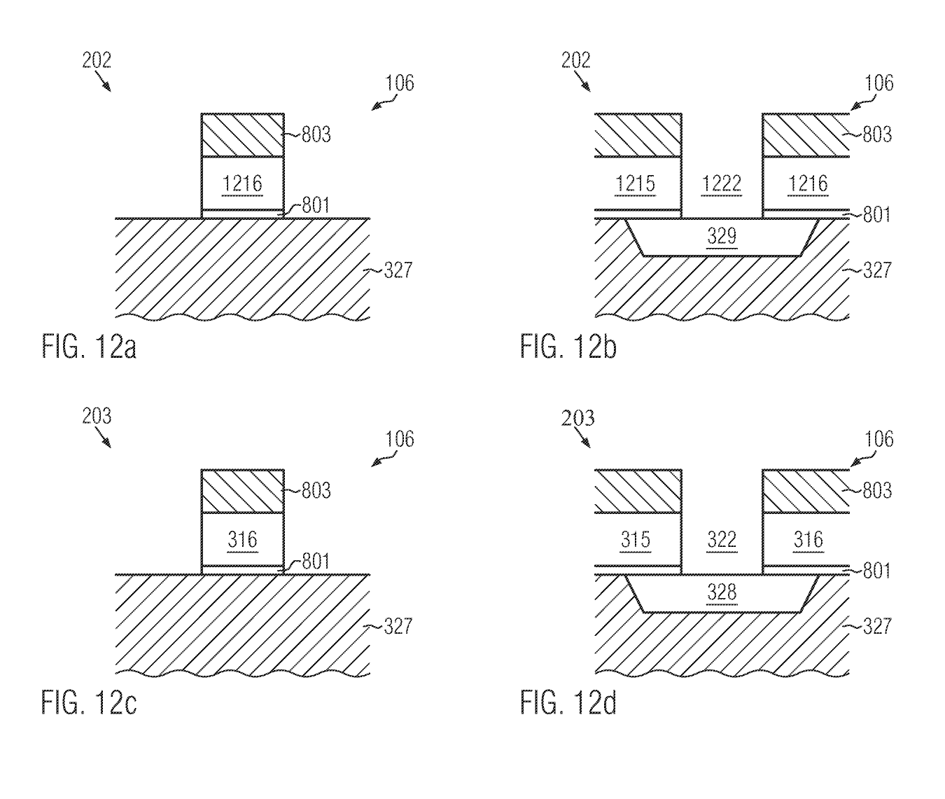

FIGS. 8a and 8b show schematic cross-sectional views of a portion of the semiconductor structure 106 at a location in the logic circuit area 202 wherein two adjacent gate structures that are based on an elongated gate line feature and are separated by a gate cut are to be formed. FIG. 8a shows a cross-section along a direction that is perpendicular to a longitudinal direction of the elongated gate line feature and is located adjacent to the gate cut. After the completion of the formation of the gate structures, the cross-section of FIG. 8a runs through one of the gate structures 1216 (see FIG. 12a). FIG. 8b shows a cross-sectional view along the longitudinal direction of the elongated gate line feature, wherein a gate cut 1222 (see FIG. 12b) is formed at a location corresponding to the center of FIG. 8b.

FIG. 8c shows a schematic cross-sectional view of a portion of the semiconductor structure 106 in the memory array area 203 along a direction that is perpendicular to a longitudinal direction of an elongated gate line feature. FIG. 8d shows a schematic cross-sectional view along the longitudinal direction of the elongated gate line feature in the memory array area 203. In FIG. 3, the location of the portion of the semiconductor structure 106 shown in cross-sectional view in FIGS. 8c and 8d is denoted by reference numeral 324, wherein dash-dotted line 325 illustrates the location of the cross-section of FIG. 8c and dash-dotted line 326 illustrates the location of the cross-section of FIG. 8d.

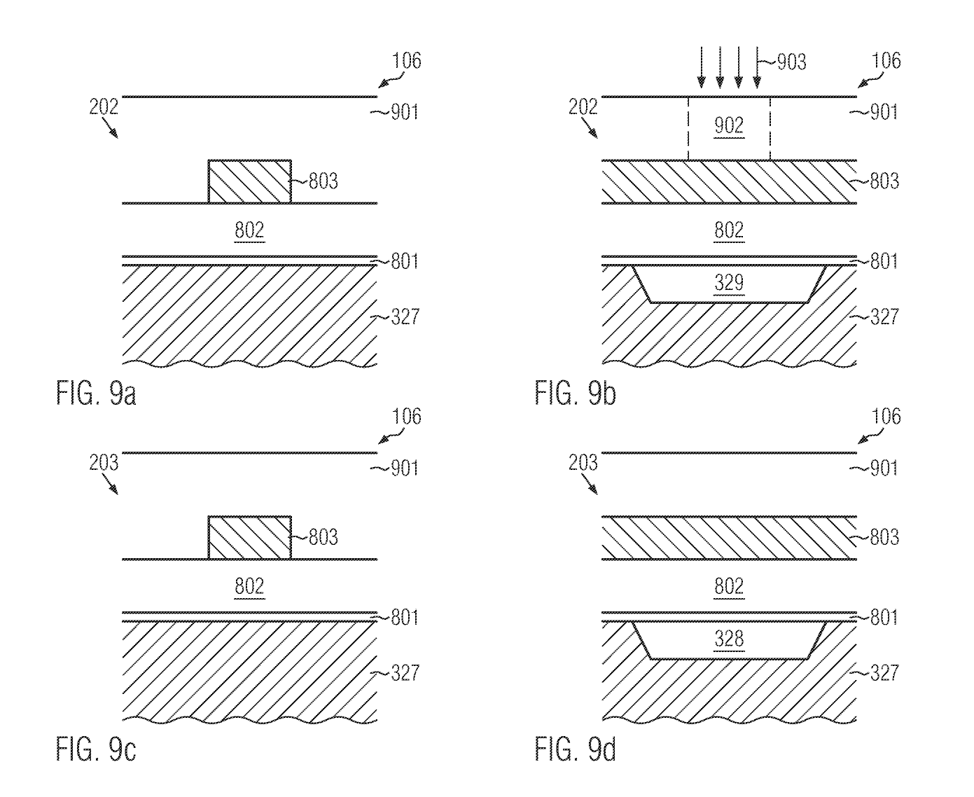

FIGS. 9a, 10a, 11a and 12a show schematic cross-sectional views of the portion of the semiconductor structure 106 shown in FIG. 8a in later stages of the manufacturing process. Similarly, FIGS. 9b, 10b, 11b and 12b show cross-sections corresponding to the cross-section of FIG. 8b, FIGS. 9c, 10c, 11c and 12c show cross-sections corresponding to the cross-section of FIG. 8c, and FIGS. 9d, 10d, 11d and 12d show cross-sections corresponding to the cross-section of FIG. 8d in later stages of the manufacturing process.

At the stage of the manufacturing process illustrated in FIGS. 8a-8d, the semiconductor structure 106 includes a layer 801 of a gate insulation material. The layer 801 of the gate insulation material may be provided over the semiconductor material of the substrate 327 of the semiconductor structure 106, as well as over trench isolation structures in the semiconductor structure 106. In FIG. 8b, reference numeral 329 denotes a trench isolation structure provided in the logic circuit area 202. In FIG. 8d, reference numeral 328 denotes the trench isolation structure 328 provided in the memory array area 203 that is also shown in FIG. 3.

The gate insulation material of the layer 801 may include silicon dioxide and/or a high-k material having a greater dielectric constant than silicon dioxide, for example, hafnium oxide, zirconium oxide and/or hafnium zirconium oxide.

Over the layer 801 of gate insulation material, a layer 802 of a gate structure material may be provided. The gate structure material of the layer 802 may include polysilicon and/or one or more metals.

In some embodiments, the layers 801, 802 may include materials that remain in the semiconductor structure 106 after the completion of the manufacturing process. In other embodiments, the layer 801 of gate insulation material and/or the layer 802 of gate structure material may include materials of dummy gate insulation layers and dummy gate electrodes, respectively, that are replaced by final gate insulation layers and final gate structures in later stages of the manufacturing process. For forming the final gate insulation layers and the final gate structures, conventional replacement gate techniques may be used.

In further embodiments, the layer 802 of gate structure material may include a material of dummy gate structures that are replaced by final gate structures in later stages of the manufacturing process, and the layer 801 may include a material of final gate insulation layers that remains in the semiconductor structure 106 after the completion of the manufacturing process. For forming the final gate structures, conventional partial replacement gate techniques may be used.

Over the layer 802 of gate structure material, a layer 803 of a hardmask material may be provided. The layer 803 of hardmask material may include silicon dioxide, silicon oxynitride and/or silicon nitride.

Over the layer 803 of hardmask material, a photoresist mask 804 may be provided. The photoresist mask 804 may be provided over portions of the semiconductor structure 106 wherein elongated gate line features are to be formed.

The above-described features may be formed by means of conventional semiconductor manufacturing techniques. In particular, the trench isolation structures 328, 329 may be formed by means of conventional techniques for the formation of shallow trench isolation (STI) structures including photolithography, etching, oxidation, deposition and/or chemical mechanical polishing. The layer 801 of gate insulation material, the layer 802 of gate structure material and the layer 803 of hardmask material may be formed by means of conventional deposition techniques such as atomic layer deposition, chemical vapor deposition and/or plasma-enhanced chemical vapor deposition. The photoresist mask 804 may be formed by means of a photolithography process.

FIGS. 9a-9d show schematic cross-sectional views of the semiconductor structure 106 at a later stage of the manufacturing process. An etch process, for example, a dry etch process adapted to remove the hardmask material of the layer 803, may be performed in the presence of the photoresist mask 804. In the etch process, portions of the layer 803 of hardmask material that are not covered by the photoresist mask 804 may be removed. In doing so, the layer 803 of hardmask material is patterned on the basis of the elongated gate line features extending perpendicular to the planes of drawing of FIGS. 9a and 9c, and in the horizontal direction in the planes of drawing of FIGS. 9b and 9d. Accordingly, FIGS. 9b and 9d show cross-sections of elongated gate line features formed from the layer 803 of hardmask material along the longitudinal directions of the elongated gate line features, and FIGS. 9a and 9c show cross-sectional views of the elongated gate line features along directions that are perpendicular to the longitudinal directions of the elongated gate line features.

After the etch process, the photoresist mask 804 may be removed by means of a photoresist strip process, and a photoresist layer 901 may be formed over the semiconductor structure 106, for example by means of a spin-coating process.

Then, a photoresist exposure process for providing a gate cut photoresist pattern over the logic circuit area 202 in the chip area 201 of the semiconductor structure 106 may be performed. For this purpose, the semiconductor structure 106 may be inserted into a photolithography tool, for example, the photolithography tool 100 illustrated in FIG. 1, and the photomask 401 may be inserted into the photolithography tool 100 as the photomask 104. Additionally, an illumination aperture configured to provide an illumination source pattern adapted to the arrangement of photomask features 404 to 406 of the photomask 401 may be inserted into the photolithography tool 100 as the illumination aperture 102. In some embodiments, the illumination aperture 601 providing a quadrupole illumination pattern that is shown in FIG. 6a may be used. In other embodiments, the illumination aperture 606 providing an annular illumination pattern that is shown in FIG. 6b may be used.

Thereafter, the light source 101 of the photolithography tool 100 may be operated for illuminating the photomask 401 on the basis of the illumination pattern provided by the illumination aperture, and for projecting the photomask 401 to the photoresist layer 901. In doing so, areas of the photoresist layer 901 at the location of gate cuts to be provided in the logic circuit area 202 are exposed. In FIG. 9b, one of the exposed areas of the photoresist layer 901 is denoted by reference numeral 902, and the light from the light source 101 impinging on the exposed area 902 of the photoresist layer 901 is schematically illustrated by arrows 903.

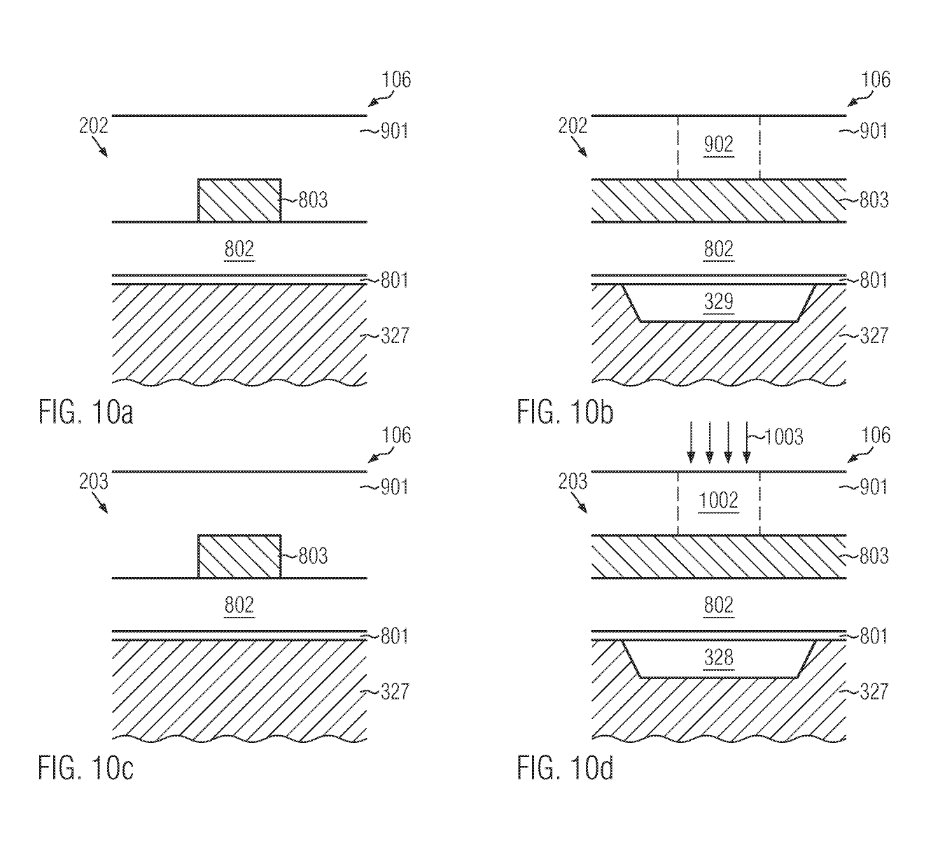

FIGS. 10a-10d show schematic cross-sectional views of the portions of the semiconductor structure 106 in a later stage of the manufacturing process. After performing the photoresist exposure process described above with reference to FIGS. 9a-9d, wherein the photomask 401 and an illumination source pattern appropriate for the photomask 401 are used, another photoresist exposure process may be performed for providing a gate cut photoresist pattern over the memory array area 203 in the chip area 201 of the semiconductor structure 106. For this purpose, the photomask 501 described above with reference to FIG. 5, and an illumination source pattern that is appropriate for the photomask 501 and different from the illumination source pattern used for the photomask 401 may be used.

The semiconductor structure 106 may be provided in a photolithography tool, for example, the photolithography tool 100 described above with reference to FIG. 1. The photomask 501 may be provided as the photomask 104 in the photolithography tool 100, and an illumination aperture adapted for use with the photomask 501 such as, for example, the illumination aperture 701 shown in FIG. 7a or the illumination aperture 706 shown in FIG. 7b may be provided as the illumination aperture 102.

The photomask 501 may be illuminated on the basis of the illumination pattern provided by the illumination aperture 701 or the illumination aperture 706, respectively, and the photomask 501 may be projected to the photoresist layer 901. In doing so, portions of the photoresist layer 901 at locations in the memory array area 203 wherein gate cuts are to be provided may be exposed. In FIG. 10d, reference numeral 1002 denotes an exposed area of the photoresist layer 901 at the location of the gate cut 322 shown in FIG. 3, and arrows 1003 denote the light exposing the area 1002 of the photoresist layer 901.

The present disclosure is not limited to embodiments wherein the photoresist exposure process using the photomask 401 is performed before the photoresist exposure process using the photomask 501. In other embodiments, the photoresist exposure process using the photomask 501 may be performed before the photoresist exposure process using the photomask 401.

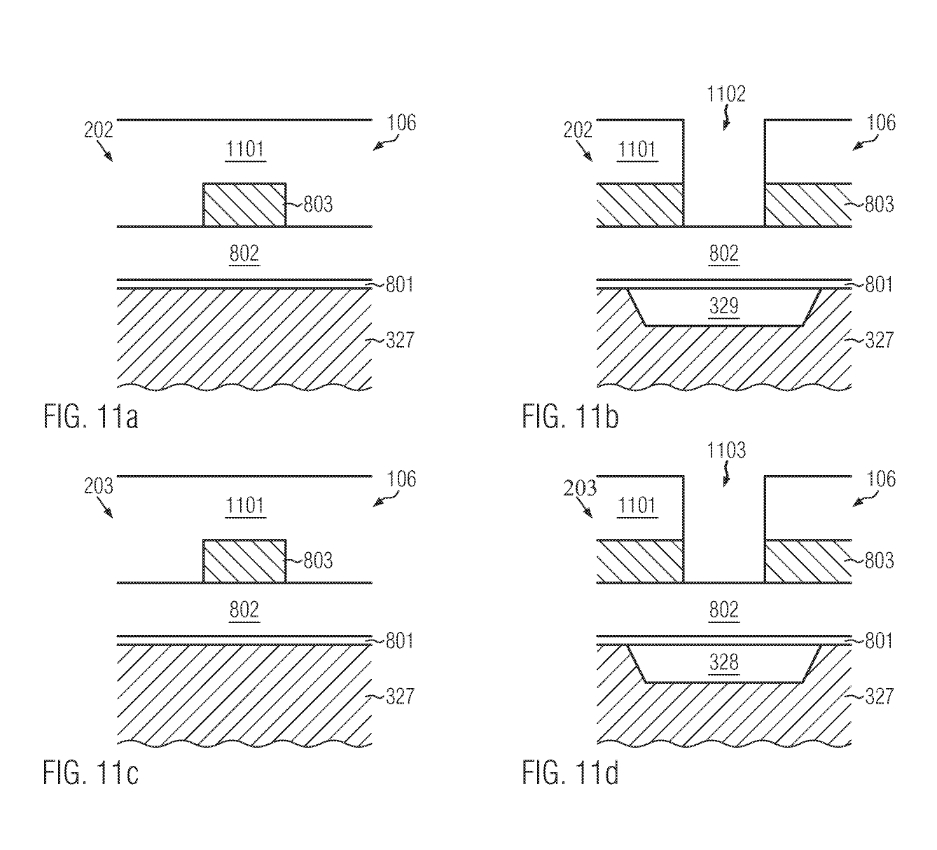

FIGS. 11a-11d show schematic cross-sectional views of the portions of the semiconductor structure 106 in a later stage of the manufacturing process. After the photoresist exposure processes described above with reference to FIGS. 9a-10d, the photoresist layer 901 may be developed. In doing so, portions of the photoresist of the photoresist layer 901 in the exposed areas 902, 1002 are removed from the semiconductor structure 106. Unexposed portions of the photoresist layer 901 may remain in the semiconductor structure 106. Thus, a photoresist mask 1101 having openings 1102, 1103 at the locations of the semiconductor structure 106 wherein gate cuts are to be provided may be formed from the photoresist layer 901.

Thereafter, an etch process, for example, a dry etch process, adapted for removing the material of the layer 803 of hardmask material may be performed in the presence of the photoresist mask 1101. In doing so, the layer 803 of hardmask material is patterned on the basis of a plurality of gate cuts, wherein the elongated gate line features, that were formed from the layer 803 of hardmask material, are cut so that a hardmask having a configuration corresponding to the configuration of the gate structures to be formed in the semiconductor structure 106 is obtained. Thereafter, the photoresist mask 1101 may be removed from the semiconductor structure 106 by means of a photoresist strip process.

FIGS. 12a-12d show schematic cross-sectional views of the portions of the semiconductor structure 106 in later stages of the manufacturing process. An etch process adapted to remove the material of the layer 802 of gate structure material and/or the material of the layer 801 of gate insulation material may be performed in the presence of the hardmask formed from the layer 803 of hardmask material. Thus, a pattern of gate structures corresponding to the hardmask may be obtained.

In particular, in the memory array area 203, gate structures 315, 316, as well as the other gate structures 312, 313, 314, 317 shown in FIG. 3, may be formed. Additionally, gate structures 1215, 1216 may be formed in the logic circuit area 202. Between the gate structures 315, 316, gate cut 322 may be provided, and a gate cut 1222 may be provided between the gate structures 1215, 1216.

After the etch process, a configuration of the bitcells 301, 301′ in the memory array area 203 as described above with reference to FIG. 3 may be obtained.

In some embodiments, the hardmask 803 may be removed from the semiconductor structure 106 after the etching of the layers 801, 802. In other embodiments, the hardmask 803 may remain in the semiconductor structure 106, and provide cap-layers of the gate structures in the semiconductor 106.

Thereafter, conventional semiconductor manufacturing techniques for forming interlayer dielectric layers and metallization layers over the semiconductor structure 106 and, optionally, replacement gate processes or partial replacement gate processes may be performed.

The present disclosure is not limited to embodiments wherein planar transistors are provided in the semiconductor structure 106, as shown in FIGS. 3 and 8a to 12d. In other embodiments, FinFET transistors and/or trigate transistors may be employed.

Furthermore, the present disclosure is not limited to embodiments wherein the layer 803 of hardmask material is used, and a hardmask which is then used for patterning the layer 802 of gate structure material and/or the layer 801 of gate insulation material is formed. In other embodiments, the layer 803 of hardmask material may be omitted, and the layer 802 of gate structure material and/or the layer 801 of gate insulation material may be patterned on the basis of the photoresist masks 804, 1101.

Moreover, the present disclosure is not limited to embodiments wherein illumination apertures are used for providing illumination source patterns. In other embodiments, diffractive optical elements may be used for providing illumination source patterns. In particular, in some embodiments, a diffractive optical element may be used for providing a freeform illumination pattern of the photomask 501.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed:

1. A method, comprising:
providing a semiconductor structure;
forming a plurality of gate structures over said semiconductor structure, the formation of said plurality of gate structures comprising a first patterning process, said first patterning process comprising:
a first photoresist exposure process wherein a first photomask and a first illumination source pattern are used, said first photomask being adapted for providing a first gate cut photoresist pattern over a first area of said semiconductor structure; and
a second photoresist exposure process wherein a second photomask and a second illumination source pattern that is different from said first illumination source pattern are used, said second photomask being adapted for providing a second gate cut photoresist pattern over a second area of said semiconductor structure.

2. The method of claim 1, wherein circuits of a different type are formed in said first area of said semiconductor structure and said second area of said semiconductor structure.

3. The method of claim 2, wherein at least said second illumination pattern comprises an off-axis illumination pattern.

4. The method of claim 3, wherein said second photomask comprises a plurality of photomask features, wherein a greater part of said plurality of photomask features has a greater extension in a first direction than in a second direction, said second direction being perpendicular to said first direction.

5. The method of claim 4, wherein said second illumination source pattern comprises at least one of a dipole illumination pattern and a freeform illumination pattern.

6. The method of claim 5, wherein a memory array is formed in said second area of said semiconductor structure.

7. The method of claim 6, wherein said memory array comprises a static random access memory array.

8. The method of claim 7, wherein a logic circuit is formed in said first area of said semiconductor structure.

9. The method of claim 8, wherein said first illumination source pattern comprises at least one of a quadrupole illumination pattern and an annular illumination pattern.

10. The method of claim 9, wherein said first patterning process further comprises:
forming a photoresist layer over said semiconductor structure;
wherein said first photoresist exposure process comprises illuminating said first photomask on the basis of said first illumination pattern and projecting said first photomask to said photoresist layer.

11. The method of claim 10, wherein said second photoresist exposure process comprises illuminating said second photomask on the basis of said second illumination pattern and projecting said second photomask to said photoresist layer.

12. The method of claim 11, wherein said first patterning process further comprises developing said photoresist after said first photoresist exposure process and said second photoresist exposure process, wherein a photoresist mask comprising said first gate cut photoresist pattern and said second gate cut photoresist pattern is formed.

13. The method of claim 12, further comprising providing a first illumination aperture, said first illumination aperture defining said first illumination source pattern, wherein said first photoresist exposure process comprises inserting said first illumination aperture into an optical path of a photolithography tool on a side of said first photomask that is opposite said semiconductor structure.

14. The method of claim 13, further comprising providing a second illumination aperture, said second illumination aperture defining said second illumination source pattern, wherein said second photoresist exposure process comprises inserting said second illumination aperture into an optical path of said photolithography tool on a side of said second photomask that is opposite said semiconductor structure.

15. The method of claim 14, wherein the formation of said plurality of gate structures further comprises performing a second patterning process, wherein said second patterning process defines a plurality of elongated gate line features and said first patterning process defines a plurality of cuts of said plurality of elongated gate line features.

16. The method according to claim 15, wherein the formation of said plurality of gate structures further comprises forming a hardmask, the formation of said hardmask comprising:
forming a layer of a hardmask material over said semiconductor structure;
wherein, in said second patterning process, said layer of hardmask material is patterned on the basis of said plurality of elongated gate line features; and
in said first patterning process, said layer of hardmask material is patterned on the basis of said plurality of cuts of said plurality of elongated gate line features.

17. The method of claim 16, wherein the formation of said plurality of gate structures further comprises performing an etch process adapted to remove a gate structure material below said hardmask, said etch process being performed in the presence of said hardmask.

18. The method of claim 17, wherein said second patterning process is performed before said first patterning process.

19. The method of claim 18, wherein said plurality of gate structures provides gate electrodes of a plurality of transistors.

20. The method of claim 19, wherein said plurality of gate structures provides dummy gate electrodes of a plurality of transistors.
